(19) United States
(12) Patent Application Publication
(10) Pub. No.: US 2013/0241628 A1
(43) Pub. Date: Sep. 19, 2013

(54) METHODS AND SYSTEMS FOR IMPLEMENTING AN SCR TOPOLOGY IN A HIGH VOLTAGE SWITCHING CIRCUIT

(71) Applicant: Jin Zhang, Porter Ranch, CA (US)

(72) Inventor: Jin Zhang, Porter Ranch, CA (US)

(73) Assignee: PACESETTER, INC., Sylmar, CA (US)

(21) Appl. No.: 13/420,003

(22) Filed: Mar. 14, 2012

(51) Int. Cl. H03K 17/72

(52) U.S. Cl. 327/439

(57) ABSTRACT

In accordance with an embodiment, a high voltage switching and control circuit for an implantable medical device (IMD) is provided that comprises a high voltage positive (HVP) node configured to receive a positive high voltage signal from a high energy storage source; and a high voltage negative (HVN) node configured to receive a negative high voltage signal from a high energy storage source. First and second output terminals are configured to be connected to electrodes for delivering high voltage energy. First and second Silicon Controlled Rectifiers (SCR) switches are connected to the HVP node, the first and second SCR switches connected to the first and second output terminals respectively, wherein the first and second SCR switches each include a Darlington transistor pair having a first transistor stage joined to a second stage transistor at a common collector node.

### BACKGROUND OF THE INVENTION

Embodiments are described herein that relate generally to medical devices for treating various cardiac, physiologic and neurologic disorders. More particularly, embodiments are described that relate to implantable or external medical devices with a high voltage delivery circuit.

Numerous medical devices exist today, including but not limited to electrocardiographs (“ECGs”), electroencephalographs (“EEGs”), squid magnetometers, implantable pacemakers, implantable cardioverter-defibrillators (“ICDs”), neurostimulators, electrophysiology (“EP”) mapping and radio frequency (“RE”) ablation systems, and the like (hereafter generally “implantable medical devices” or “IMDs”). IMDs commonly employ one or more leads with electrodes that either receive or deliver voltage, current or other electromagnetic pulses (generally “energy”) from or to an organ or tissue (collectively hereafter “tissue”) for diagnostic or therapeutic purposes.

Certain types of IMDs include internal charge storage members, such as one or more capacitors. The charge storage members are connected to a switch circuit or network also referred to as an H-bridge. Conventional high voltage H-bridges include a network of transistors that are controlled to open and close in different combinations to deliver stored energy from the charge storage members to a patient through the electrodes. Heretofore, the H-bridge circuits in IMDs have used switches implemented through IGBT (Insulated Gate Bipolar Transistors), MOS (Metal Oxide Semiconductor), BJT (Bipolar Junction Transistors), and SCR (Silicon Controlled Transistor) switches.

In many IMDs today, the high voltage bridge circuit includes two or three output terminals that are configured to be coupled to two or three separate electrodes capable of delivering high voltage energy to a patient. A network of four or six switches connects the output terminals to a high voltage positive (HVP) source and a high voltage negative (HVN) source. Each output terminal is located between, and in series with, a corresponding pair of switches (IGBT, MOS, BJT, SCR) that are located between the corresponding HVP and HVN sources. One from each pair of switches opens and closes to connect or disconnect the corresponding output terminal, to one of the HVP and HVN sources.

SCRs are smaller in size and less expensive than IGBT, MOS and BJT switches. However, SCRs exhibit different operational characteristics than IGBTs, MOS and BJTs. SCRs are latching devices, and thus once triggered, an SCR switch will stay ON as long as current is flowing through the SCR. It has been proposed to implement SCR switches as substitutes for other switches in a high voltage H-bridge circuit.

A simplified classic SCR topology contains one PNP and one NPN transistor. When applying voltage across the anode and cathode and enough external gate triggering current, the NPN transistor will turn ON and force the PNP transistor to turn ON as well. Thus, the SCR is shorted across the anode and cathode outputs, which is called SCR latch up. The latch up property of an SCR is the fundamental mechanism of the SCR switching function.

Modern CMOS low power integrated circuits (IC) can directly drive a SCR circuit. However, circuits with CMOS driven SCRs face tradeoffs. In order for a low power CMOS IC to drive a high power SCR there are three solutions: 1) Increase the CMOS driver power in IC, but it will dramatically increase the die size of CMOS; 2) Add an external power driver buffer, but this will add more cost and space of the circuit; and 3) Increase the driving sensitivity or increase the beta of the NPN bipolar transistor, but this might cause dV/dt and dl/dt problem. Only solution three will not increase circuit space and cost if dV/dt or dl/dt problem can be solved.

However, when the beta is increased, the SCR may experience certain difficulties in connection with the incremental change in current per unit time and/or incremented change in voltage per unit time (sometimes referred to as the dl/dt problem and dV/dt problem). The SCR may experience a dl/dt problem when turning ON, which occurs when the rate of rise of on-state current after triggering the SCR is higher than an amount that can be supported by the spreading speed of the active conduction area. The SCR may experience a dV/dt problem when switching ON because the SCR can be spuriously fired without trigger from the gate if the rate of rise of the voltage between the anode to cathode is too large. The dl/dt and dV/dt problems are caused by the high speed (or wide bandwidth) input signal and high gain (large beta) of the BJT transistor inside the SCR. In the worst case scenario, a sensitive SCR may be triggered by input noise spark.

To address these problems, a SCR designer will usually reduce the gain of the internal BJT in the SCR (especially the Bipolar Junction Transistor of the NPN transistor) and shunt a small gate resistor to split the driving current, thus reducing the gate sensitivity. At the same time, it may be desirable to limit the driving speed of the external triggering source to this particular SCR.

The SCRs may be used in high voltage H-bridge circuits to replace the MOS or IGBTs in the upper circuit and thus eliminate an expensive isolation transformer or optical insulation driver which are used with IGBTs. This simplifies the driver circuit and reduces cost, especially in direct IC driven circuits. The cost of implementing this design is just adding one protection diode in the gate of the SCR.

A typical H-Bridge in an IMD contains two or three upper SCRs. It may experience high impedance load limit problems (e.g. <350 Ohm load in ICD H-bridge). This is to say, when firing under a high impedance load, an SCR may either not have enough holding current (related to internal NPN BJT beta and power driving capability) or not have enough triggering current. The SCR manufacturer may modify the internal transistor parameters, such as to increase the NPN BJT beta and power, thereby improving the high impedance load driving capability. However, increasing the NPN BJT beta will intrinsically bring back the dl/dt and dV/dt problem. In order to mitigate the dl/dt and dV/dt problem, a typical solution is to shunt a small resistor R1 between the gate and cathode nodes to reduce the sensitivity of the NPN transistor. However, the shunt gate resistor will increase the triggering current. Hence, the SCR's dl/dt and dV/dt problems are the root cause for high driving/holding current, low driving capability under high impedance load application for an SCR. These tradeoffs between the dl/dt and dV/dt problem, high triggering/holding current, high impedance loading capability are due to internal transistor limitations, especially the internal NPN, or due to single BJT tradeoffs.

### SUMMARY

In accordance with embodiments herein an improved SCR topology is provided for an H-bridge circuit that eliminates the above noted problems.

In accordance with an embodiment, a high voltage switching and control circuit for an implantable medical device (IMD) is provided that comprises a high voltage positive (HVP) node configured to receive a positive high voltage signal from a high energy storage source; and a high voltage negative (HVN) node configured to receive a negative high voltage signal from a high energy storage source. First and second output terminals are configured to be connected to electrodes for delivering high voltage energy. First and second Silicon Controlled Rectifiers (SCR) switches are connected to the HVP node, the first and second SCR switches connected to the first and second output terminals respectively, wherein the first and second SCR switches each include a Darlington transistor pair having a first transistor stage joined to a second stage transistor at a common collector node.

In accordance with an embodiment, the first and second stages of the Darlington transistor pair are joined such that an emitter of the first stage is connected to a base of the second stage. Optionally, the first and second stages of the Darlington transistor pair are joined such that emitters of the first and second stages are joined to first and second output nodes that have a shunt resistor provided therebetween. Optionally, the first and second stages have operational parameters set such that a predetermined triggering current will turn ON and hold ON the corresponding SCR switch.

Optionally, the first and second stages have operational parameters set such that the corresponding SCR switch exhibits predetermined dV/dt and dl/dt characteristics. Optionally, the first and second stages have first and second beta values, respectively, that are set to limit a rate of rise of an anode to gate voltage across the Darlington transistor pair in a predetermined manner to thereby prevent false triggering of the corresponding SCR switch when connected to a predetermined load and supplied with a predetermined triggering signal.

The first and second stages may be configured to exhibit corresponding beta and power operational parameters, the beta and power operational parameters of the first stage being lower than the beta and power operational parameters of the second stage to reduce a sensitivity at the gate node of the first stage and to reduce a drive current delivered to the gate node of the first stage. Optionally, the first and second stages are configured to exhibit corresponding betas and power, the beta and power of the second stage being higher than the beta and power of the first stage to increase an output drive capability of the SCR switch. Optionally, the second output terminal represents a SVC terminal configured to be connected to a Superior Vena Cava (SVC) electrode. Optionally, the IMD comprises additional switches, the output terminals, first and second SCR switches and additional switches being arranged in an H-bridge having output terminals.

In accordance with an embodiment, a method is provided for operating a high voltage switching and control circuit in an implantable medical device (IMD). The method comprises configuring a high voltage positive (HVP) node to receive a positive high voltage signal from a high energy storage source; and configuring a high voltage negative (HVN) node to receive a negative high voltage signal from a high energy storage source. The method further comprises configuring first and second output terminals to be connected to electrodes for delivering high voltage energy; and connecting first and second Silicon Controlled Rectifiers (SCR) switches to the HVP node, the first and second SCR switches connected to the first and second output terminals respectively, wherein the first and second SCR switches each include a Darlington transistor pair having a first transistor stage joined to a second stage transistor at a shared collector node. In accordance with an embodiment, the first and second stages of the Darlington transistor pair are joined such that an emitter of the first stage is connected to a base of the second stage.

### BRIEF DESCRIPTION OF THE DRAWINGS

FIG. 1 is a simplified view of an exemplary implantable medical device in electrical communication with leads implanted into a patient's heart in accordance with an embodiment.

FIG. 2 is a functional block diagram of the IMD of FIG. 1.

FIG. 3 is a simplified block diagram of a portion of an IMD for delivering high energy shocks in accordance with an embodiment.

FIG. 4 is a high voltage switching circuit formed in accordance with an embodiment.

FIG. 5 illustrates a schematic arrangement for an SCR formed in accordance with an embodiment.

FIG. 6A illustrates a schematic design of an SCR formed in accordance with an embodiment.

FIG. 6B illustrates a simulation of the output of the SCR where the horizontal axis plots time in microseconds, the left vertical axis plots voltage in Volts and the right vertical axis plots current in milliamps.

FIG. 6C illustrates another simulation result of the output of the SCR where the horizontal axis plots time in microseconds, the left vertical axis plots voltage in Volts and the right vertical axis plots current in milliamps.

FIG. 7A illustrates a schematic design of an SCR formed in accordance with an embodiment.

FIG. 7B illustrates a simulation result of the output of the SCR where the horizontal axis plots time in microseconds, the left vertical axis plots voltage in Volts and the right vertical axis plots current in milliamps.

FIG. 7C illustrates another simulation of the output of the SCR where the horizontal axis plots time in microseconds, the left vertical axis plots voltage in Volts and the right vertical axis plots current in milliamps.

FIG. 8A illustrates a schematic design of a classical SCR formed in accordance with a conventional design.

FIG. 8B illustrates a simulation of the output of the classic SCR.

FIG. 8C illustrates a simulation result of the output of the classic SCR.

FIG. 8D illustrates a simulation result of the output of the classic SCR.

### DETAILED DESCRIPTION

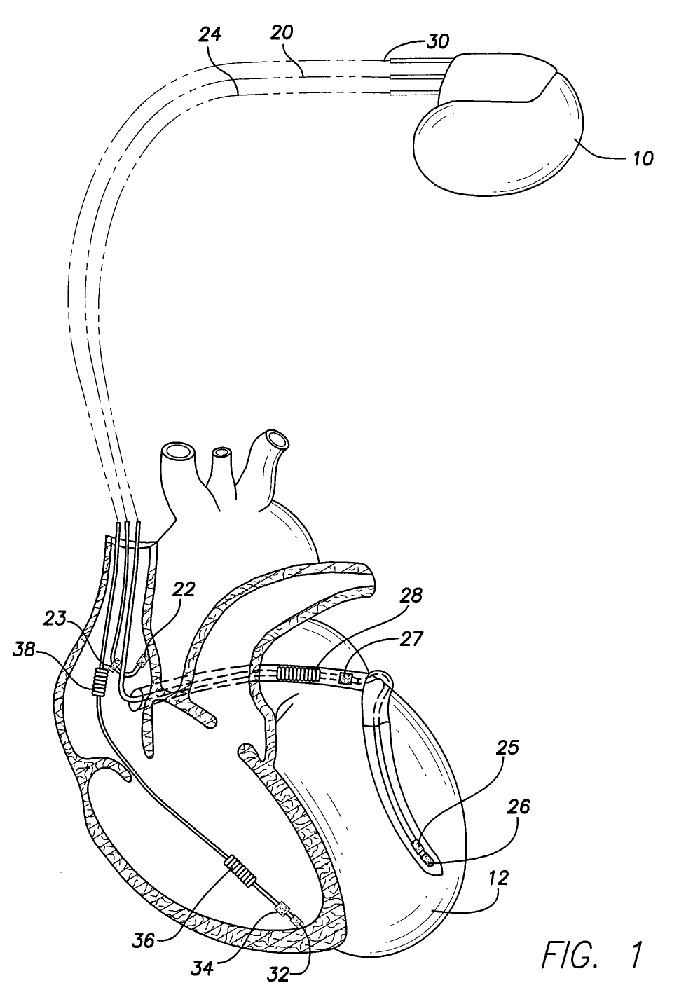

FIG. 1 illustrates an IMD 10 in electrical communication with a patient's heart 12 by way of three leads 20, 24 and 30 suitable for delivering multi-chamber stimulation and/or shock therapy. To sense atrial cardiac signals and to provide right atrial chamber stimulation therapy, the IMD 10 is coupled to an implantable right atrial lead 20 including at least one atrial tip electrode 22 that typically is implanted in the patient's right atrial appendage. The right atrial lead 20 may also include an atrial ring electrode 23 to allow bipolar stimulation or sensing in combination with the atrial tip electrode 22.

To sense the left atrial and left ventricular cardiac signals and to provide left-chamber stimulation therapy, the IMD 10 is coupled to a “coronary sinus” lead 24 designed for placement in the “coronary sinus region” via the coronary sinus ostium in order to place a distal electrode adjacent to the left ventricle and additional electrode(s) adjacent to the left atrium. As used herein, the phrase “coronary sinus region” refers to the venous vasculature of the left ventricle, including any portion of the coronary sinus, great cardiac vein, left marginal vein, left posterior ventricular vein, middle cardiac vein, and/or small cardiac vein or any other cardiac vein accessible by the coronary sinus.

Accordingly, the coronary sinus lead 24 is designed to: 1) receive atrial and/or ventricular cardiac signals, 2) deliver left ventricular pacing therapy using at least one left ventricular tip electrode 26 for unipolar configurations or in combination with left ventricular ring electrode 25 for bipolar configurations, and 3) deliver left atrial pacing therapy using at least one left atrial ring electrode 27 as well as shocking therapy using at least one left atrial coil electrode 28.

The IMD 10 is also shown in electrical communication with the patient's heart 12 by way of an implantable right ventricular lead 30 including, in the embodiment, a right ventricular (RV) tip electrode 32, a right ventricular ring electrode 34, a right ventricular coil electrode 36, a superior vena cava (SVC) coil electrode 38, and so on. Typically, the right ventricular lead 30 is inserted transvenously into the heart 12 so as to place the right ventricular tip electrode 32 in the right ventricular apex such that the RV coil electrode 36 is positioned in the right ventricle and the SVC coil electrode 38 will be positioned in the right atrium and/or superior vena cava. Accordingly, the right ventricular lead 30 is capable of receiving cardiac signals, and delivering stimulation in the form of pacing and shock therapy to the right ventricle.

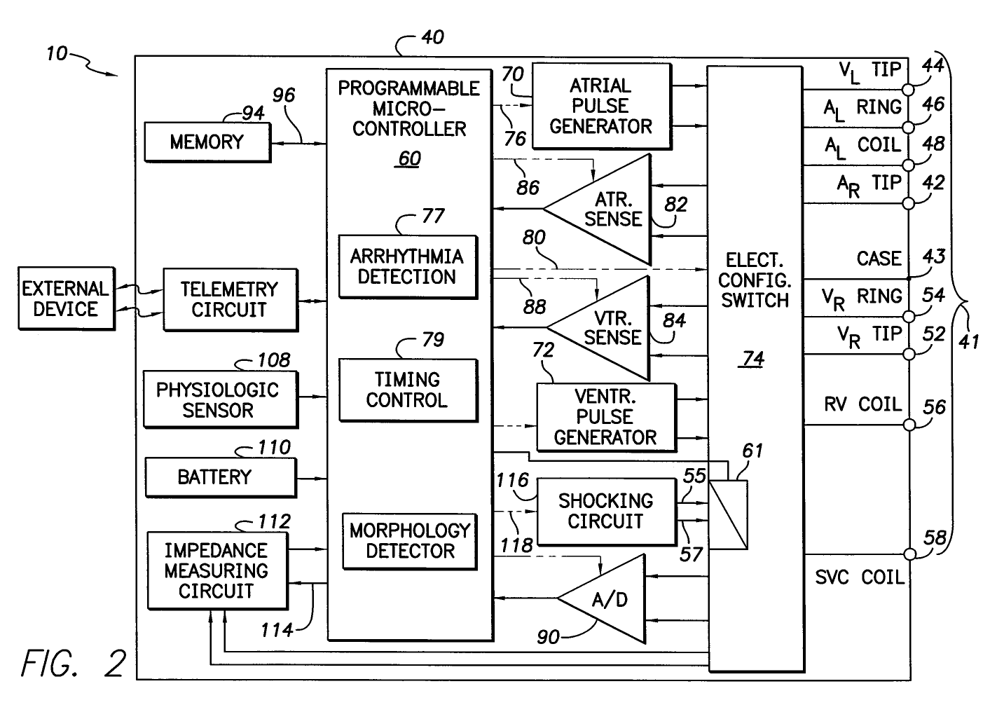

FIG. 2 illustrates a simplified block diagram of the multi-chamber IMD 10, which is capable of treating both fast arrhythmia and slow arrhythmia with stimulation therapy, including cardioversion, defibrillation, and pacing stimulation. While a particular multi-chamber device is shown, the multi-chamber device is for illustration purposes only, and one of ordinary skill in the pertinent art could readily duplicate, eliminate or disable the appropriate circuitry in any desired combination to provide a device capable of treating the appropriate chamber(s) with cardioversion, defibrillation, and/or pacing stimulation.

The IMD 10 includes a housing 40 which is often referred to as “can,” “case,” or “case electrode,” and which may be programmably selected to act as the return electrode for all “unipolar” modes. The housing 40 may further be used as a return electrode alone or in combination with one or more of the coil electrodes 28, 36, or 38, for defibrillation shocking purposes. The housing 40 further includes a connector 41 having a plurality of terminals 42, 43, 44, 45, 46, 48, 52, 54, 56, and 58 (shown schematically and, for convenience, the names of the electrodes to which they are connected are shown next to corresponding terminals). As such, in order to achieve right atrial sensing and stimulation, the connector 41 includes at least one right atrial tip terminal (RA TIP) 42 adapted for connection to the atrial tip electrode 22. The connector 41 may also include a right atrial ring terminal (RA RING) for connection to the right atrial ring electrode 23.

To achieve left chamber sensing, pacing, and/or shocking, the connector 41 may include a left ventricular tip terminal (LV TIP) 44, a left ventricular ring terminal (LV RING) 25, a left atrial ring terminal (LA RING) 46, and a left atrial shocking coil terminal (LA COIL) 48, that are adapted for connection to the left ventricular tip electrode 26, the left ventricular ring electrode 25, the left atrial ring electrode 27, and the left atrial coil electrode 28, respectively.

To support right ventricular sensing, pacing, and/or shocking, the connector 41 may further include a right ventricular tip terminal (RV TIP) 52, a right ventricular ring terminal (RV RING) 54, a right ventricular shocking coil terminal (RV COIL) 56, and an SVC shocking coil terminal (SVC COIL) 58, which are adapted for connection to the right ventricular (RV) tip electrode 32, the RV ring electrode 34, the RV coil electrode 36, and the SVC coil electrode 38, respectively.

A programmable microcontroller 60 controls the modes of stimulation therapy. The microcontroller 60 typically includes a microprocessor, or equivalent control circuitry, for controlling the delivery of stimulation therapy, and may include RAM or ROM memory, logic and timing circuitry, state machine circuitry, and/or I/O circuitry. The microcontroller 60 may have the ability to process or monitor various input signals (data) as controlled by a program code stored in a designated block of memory. The microcontroller 60 may further include timing control circuitry 79 which may be used to control timing of the stimulation pulses such as, e.g., pacing rate, atrio-ventricular (AV) delay, atrial interchamber (A-A) delay, and/or ventricular interchamber (V-V) delay.

An atrial pulse generator 70 and ventricular pulse generator 72 generate stimulation pulses for delivery by the right atrial lead 20, the right ventricular lead 30, and/or the coronary sinus lead 24 via a switch 74. The atrial pulse generator 70 and the ventricular pulse generator 72 are generally controlled by the microcontroller 60 via appropriate control signals 76 and 78, respectively, to trigger or inhibit the stimulation pulses.

The switch 74 includes a plurality of switches for connecting the desired electrodes to the appropriate I/O circuits, thereby providing complete electrode programmability. The switch 74, in response to a control signal 80 from the microcontroller 60, determines the polarity of the stimulation pulses (e.g., unipolar, bipolar, cross-chamber, and the like) by selectively closing the appropriate combination of switches. Atrial sensing circuits 82 and ventricular sensing circuits 84 may also be selectively coupled to the right atrial lead 20, coronary sinus lead 24, and the right ventricular lead 30 through the switch 74, for detecting the presence of cardiac activity in each of the four chambers of the heart.

The outputs of the atrial sensing circuit 82 and ventricular sensing circuits 84 may be connected to the microcontroller 60 for triggering or inhibiting the atrial and ventricular pulse generators 70 and 72, respectively, in a demand fashion, in response to the absence or presence of cardiac activity, respectively, in the appropriate chambers of the heart. The atrial and ventricular sensing circuits 82 and 84, in turn, may receive control signals over signal lines 86 and 88 from the microcontroller 60, for controlling the gain, threshold, polarization charge removal circuitry, and the timing of any blocking circuitry coupled to the inputs of the atrial and ventricular sensing circuits 82 and 84. For arrhythmia detection, the IMD 10 includes an arrhythmia detector 77 that utilizes the atrial and ventricular sensing circuits 82 and 84 to sense cardiac signals, for determining whether a rhythm may be physiologic or pathologic.

Cardiac signals are also applied to the inputs of a data acquisition system 90 which is depicted as an analog-to-digital (A/D) converter for simplicity of illustration. The microcontroller 60 may further be coupled to a memory 94 by a suitable data/address bus 96, wherein the programmable operating parameters used by the microcontroller 60 are stored and modified, as required, so as to customize the operation of the IMD 10 to suit the needs of particular patients. The IMD 10 may additionally include a power source, illustrated as a battery 110, for providing operating power to all the circuits of FIG. 2. For the IMD 10 employing shocking therapy, the battery 110 operates at low current drains for long periods of time, preferably less than 10 uA, and also be capable of providing high-current pulses when the patient requires a shock pulse, preferably in excess of 2 A, at voltages above 2 V, for periods of 10 seconds or more. The battery 110 preferably has a predictable discharge characteristic such that elective replacement time can be detected. A physiologic sensor 108 detects motion of the IMD and thus, patient to determine an amount of activity.

The IMD 10 includes an impedance measuring circuit 112 which is enabled by the microcontroller 60 by control signal 114. The uses for an impedance measuring circuit 112 include, but are not limited to, lead impedance surveillance during the acute and chronic phases for proper lead positioning or dislodgement; detecting operable electrodes and automatically switching to an operable pair in case dislodgement should occur; measuring respiration or minute ventilation; measuring thoracic impedance for determining shock thresholds; detecting when the device has been implanted; measuring stroke volume; detecting opening of heart valves, and so on.

The IMD 10 may be used as an implantable cardioverter defibrillator (ICD) device by detecting the occurrence of an arrhythmia, and automatically applying an appropriate electrical stimulation or shock therapy to the heart aimed at terminating the detected arrhythmia. To achieve the previously specified goal, the microcontroller 60 further controls a shocking circuit 116 by way of a control line 118. The shocking circuit 116 includes charge storage members, such as one or more capacitors. The charge storage members are charged by the battery 110 before delivering stimulating energy such as high energy shocks (e.g., 10 Joules, 20 Joules, 35 Joules). The charge storage members deliver the stimulating energy over positive and negative lines 55 and 57. The switch 74 includes a switch network 61 that is electrically disposed between the positive and negative lines 55 and 57, and the appropriate output terminals 42, 43, 44, 46, 48, 52, 54, 56, and 58 of the connector 41. The switch network 61 includes a collection of switches arranged in an H-bridge architecture that change between open and closed states to disconnect and connect the charge storage members and the desired output terminals of the connector 41.

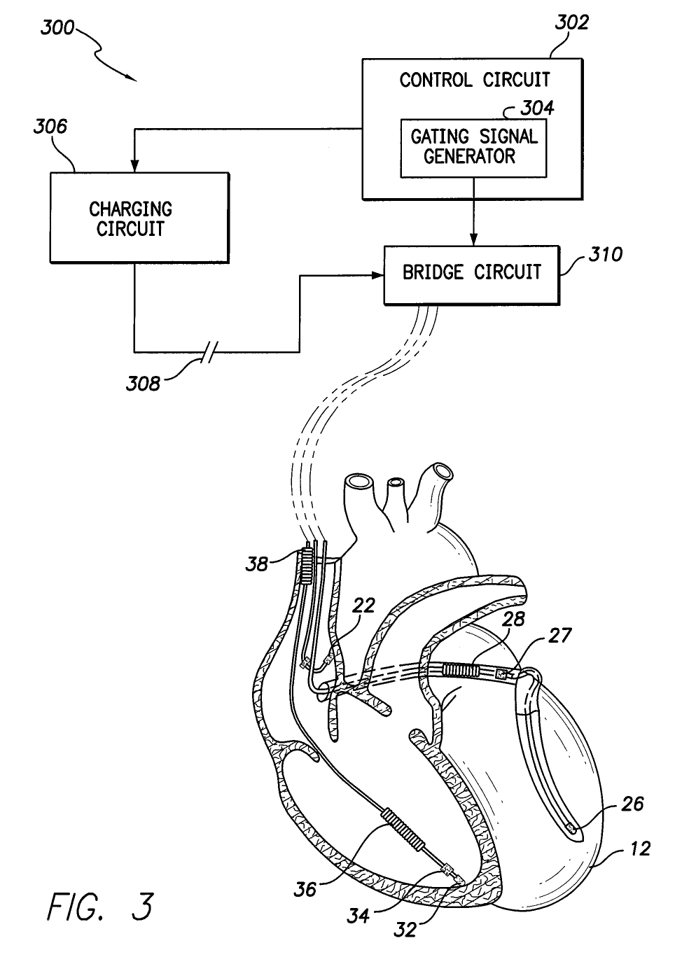

FIG. 3 is a simplified block diagram of a portion of an IMD 300 for delivering cardioversion and/or defibrillation high energy shocks in accordance with an embodiment. The IMD 300 includes a control circuit 302, a gating signal generator 304, a charging circuit 306, charge storage capacitors 308, and a bridge circuit 310. The control circuit 302 controls delivery of the cardioversion and/or defibrillation shocks. The control circuit 302 may generate commands for other components used in connection with cardioversion or defibrillation modes of operation based on programmed instructions. For example, the control circuit 302 monitors the heart action and, determines when a tachyarrhythmic condition is occurring. The control circuit 302 causes the charging circuit 306 to charge up storage capacitors 308 to a programmed setting. For example the storage capacitors 308 may be charged to 800 volts. In an embodiment, the storage capacitors 308 may be a combination of multiple capacitors to store very high charge (e.g., 20 Joules, 30 Joules, 35 Joules). Alternatively, a bank of capacitors or other energy storage devices may be used. When the charging cycle is complete, the control circuit 302 causes the gating signal generator 304 to direct the bridge circuit 310 to connect a predetermined combination of electrodes to the storage capacitor 308 and discharge the predetermined energy to select electrodes 36-28. In one embodiment, three electrodes 36-28 may be used for defibrillation. Alternatively, fewer or more than three electrodes may be used. In another embodiment, a left ventricular lead may be provided with one or multiple electrodes that operate as high energy discharge sites.

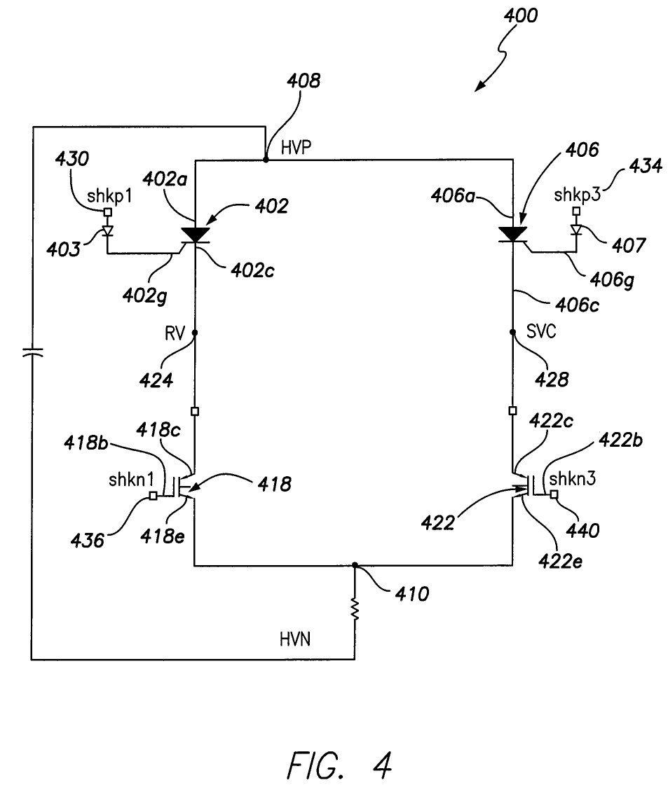

FIG. 4 illustrates a circuit diagram of a high voltage switching and control circuit 400 for an implantable medical device (IMD) formed in accordance with an embodiment. The circuit 400 includes a high voltage positive (HVP) node 408 configured to receive a positive high voltage signal from a high energy storage source, such as the storage capacitors 308 (FIG. 3). The circuit 400 includes a high voltage negative (HVN) node 410 configured to receive a negative high voltage signal from the high energy storage source (e.g., storage capacitors 308). Output terminals 424 and 428 are configured to be connected to electrodes for delivering high voltage energy to a patient. For example, the output terminal 424 may be connected to an RV electrode 36 (FIG. 1), while the output terminal 428 may be connected to a case electrode (e.g., the CASE 43) and/or an SVC electrode 38. Alternatively, either of the output terminals 424 and 428 may be connected to an LV electrode (e.g., 25), and the other output terminal 426 or 428 may be connected to an RV electrode or an LA electrode 28. Alternatively, the output terminal 424 may be connected to a combination of electrodes (e.g., LV electrodes 26 and 25), and the output terminal 428 may be connected to the case electrode (e.g., CASE 43).

The circuit 400 includes a collection of switches 402, 406, 418 and 422 arranged in an H-bridge. A first subset of the switches (e.g., 402 and 406) is positioned on the positive high voltage (or “high”) side of the output terminals 424 and 428. A second subset of the switches (e.g., 418 and 422) is positioned on the negative high voltage (or “low”) side of the output terminals 424 and 428. In the example of FIG. 4, the subset of switches (e.g., 402, 406) on the positive high voltage side are silicon controlled rectifiers, while the subset of switches (e.g., 418, 422) on the negative high voltage side are insulated bipolar gate transistors. Pairs of switches (402, 418) and (406, 422) are arranged in parallel, with opposite sides of a corresponding output terminal.

The silicon controlled rectifier (SCR) is a semiconductor device that is a member of a family of control devices known as Thyristors. The SCR is a three-lead device with an anode and a cathode (as with a standard diode) plus a third control lead, also referred to as a gate terminal. The SCR switches 402 and 406 include anodes 402a and 406a, cathodes 402c and 406c, and gating terminals 402g and 406g. As the name implies, an SCR is a rectifier which may be controlled or “triggered” to the “ON” state by applying current to the lead for the gate. Once gated ON, the gating or trigger signal may be removed and the SCR switch will remain in a conducting state as long as current flows through the SCR switch. In the example of FIG. 4, the anode 402a of the SCR switch 402 is connected to the HVP node 408 and the cathode 402c is connected to the output terminal 424. The anode 406a of the SCR switch 406 is connected to the HVP node 408 and the cathode 406c is connected to the output terminal 428. The gating terminals 402g and 406g are connected to control signal inputs 430 and 434. Optionally, isolation diodes 403 and 407 may be provided between the gating terminals 402g and 406g and the control signal inputs 430 and 434, respectively. The isolation diodes 403 and 407 isolate the control signal inputs 430 and 434 (and thus the control circuit) from the high energy that is delivered through the SCR switches 402, 406 during defibrillation or cardioversion. A control circuit delivers gating signals at the control signal inputs 430 and 434. The gating signals pass through the isolation diodes 403 and 407 to the gating terminals 402g and 406g to turn ON the SCR switches 402 and 406. By way of example, the gating signals may be delivered from the gating signal generator 304 in the control circuit 302 of FIG. 3.

The IGBT switches 418 and 422 have collectors 418c and 422c, emitters 418e and 422e, and bases 418b and 422b. The collectors 418c and 422c are connected to corresponding output terminals 424 and 428. The emitters 418e and 422e are connected to the HVN node 410. The gates 418b and 422b are connected to control signal inputs 436 and 440. Optionally, isolation components may be provided between the bases 418b and 422b and the control signal inputs 436 and 440. The control circuit delivers gating signals at the control signal inputs 436 and 440 to turn ON and OFF the IGBT switches 418 and 422. By way of example, the gating signals may be delivered from the gating signal generator 304 in the control circuit 302 of FIG. 3.

The circuit 400 is designed to enable delivery of positive or negative high voltage energy from select combinations of the two, three or more output terminals 424 and 428 based on the mode of operation and the desired shock vector(s). In the example of FIG. 4, the circuit 400 may deliver high voltage energy of a single polarity (e.g. positive) from output terminal 424, while high voltage energy of an opposite polarity (e.g., negative) is delivered from the output terminal 428. In this example, shocking vectors are created between the SVC electrode 38 (FIG. 1) and the RV electrode 36. In this example, the SCR switch 402 is connected to the HVP node 408 and to output terminal 424. A control circuit (e.g., 302 in FIG. 3) is connected to the control signal inputs 430, 434, 436 and 440.

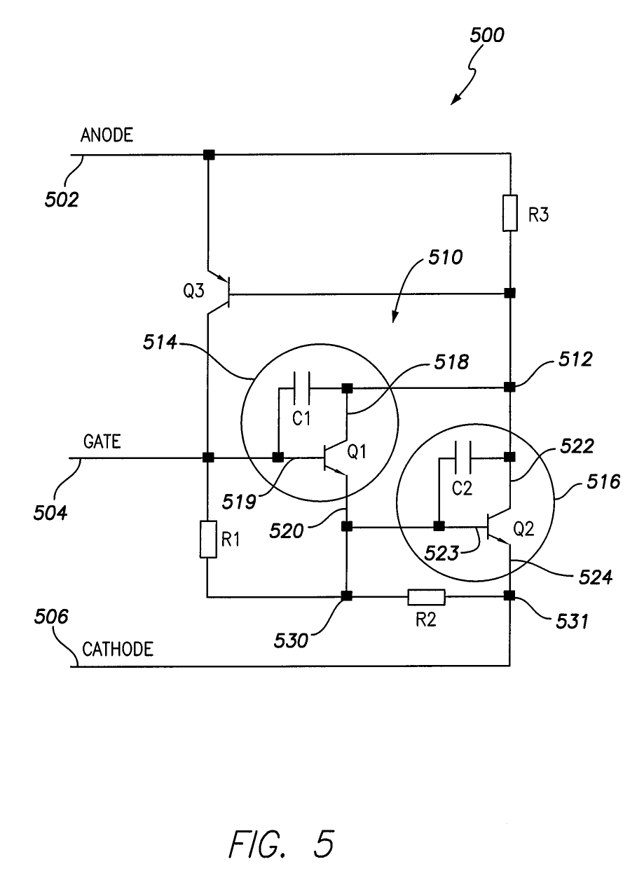

FIG. 5 illustrates a schematic arrangement for an SCR 500 formed in accordance with an embodiment of the present invention. The SCR 500 includes an anode 502, a gate node 504 and a cathode 506. A transistor Q3 is located between the anode 502 and gate node 504, while resistors R1 and R2 are located between the gate node 504 and the cathode 506. A Darlington transistor pair (DTP) 510 is positioned between a common collector node 512 and the cathode 506. The DTP 510 includes first and second stages 514 and 516 that are joined at the common collector node 512. The first (or front end) stage 514 includes a transistor Q1 with a collector 518, base 519 and emitter 520. The second (or output) stage 516 includes a transistor Q2 with a collector 522, base 523, and emitter 524. The emitter 520 of the transistor Q1 is connected to the base 523 of the transistor Q2. The emitters 520 and 524 of the first and second stages 514 and 516 are joined to stage output nodes 530 and 531. The first stage 514 exhibits a junction capacitance, denoted as capacitor C1, which is connected between the collector 518 and the base 519. The second stage 516 exhibits a junction capacitance, denoted as capacitor C2, connected between the collector 522 and the base 523.

A resistor R2 is provided between the output nodes 530 and 531 of the first and second stages 514 and 516 to account for voltage output differences there between. A shunt resistor R1 is provided between the gate node 504 and the output node 530 of the first stage 510, while a resistor R3 is provided between the anode 502 and the common collector node 512 of the first and second stages 514 and 516. In accordance with an embodiment, the operational parameters of the SCR 500 are set such that a predetermined triggering current (e.g., a low triggering current) may be used to turn ON and hold ON the SCR 500. Also, the operational parameters of the SCR 500 are set such that the SCR 500 exhibits predetermined dV/dt and dl/dt characteristics.

For example, the beta for Q1 and Q2 and C1 and C2 may be set to limit the rate of rise of the anode to gate voltage, thereby preventing false triggering of the DTP 510.

The DTP 510 utilizes a two stage transistor pair. The transistor Q1 in the first stage 514 may be configured to have a low beta and low power in order to reduce the sensitivity at the gate node 504 and in order to reduce the drive current delivered at the gate node 504 to turn ON the transistor Q1. The transistor Q2 in the second stage 516 may be configured with either a medium beta or high beta, and configured to be a high power transistor in order to increase the output driving capability of the SCR 500. As one example, the beta and power characteristics of the transistor Q2 may be set such that the SCR 500 exhibits predetermined operating characteristics when delivering high energy shocks into a high impedance load. For example, one of the operating characteristics of interest represents holding current. It may be desirable for the transistor Q2 to operate with a low or reduced holding current. As another example, other operating characteristics of interest for the DTP 500 may include utilizing transistors Q1 and Q2 that exhibit low gain (or sensitivity) at high frequency, which greatly reduces the dV/dt problem, and the dI/dt problem.

The DTP 510 may be configured to exhibit a relatively large Miller capacitance. As the Miller capacitance increases, the NPN transistor (Q1 or Q2) within the DTP 510 becomes less sensitive to wide bandwidth or high frequency noise. The SCR 500 has intrinsic immunity to high frequency gate spark noise. As a result, it may be desirable to omit or increase the gate shunt resistors (R1 and R2) that may otherwise be used to absorb part of the gate noise and reduce the sensitivity of the SCR 500. Optionally, the SCR 500 may have increase the resistance of the gate shunt resistor R1 in order to reduce the level of the triggering current needed to trigger the SCR 500. The Miller capacitance in a single BiPolar Junction Transistor approximately equals the product of the intrinsic capacitance and the beta (e.g., C1×the beta of Q1). However, the total Miller capacitance in a Darlington transistor pair approximately equals the first intrinsic capacitance C1 of Q1 times the total beta of the DTP 510 (e.g., C1×Q1 Beta×Q2 Beta).

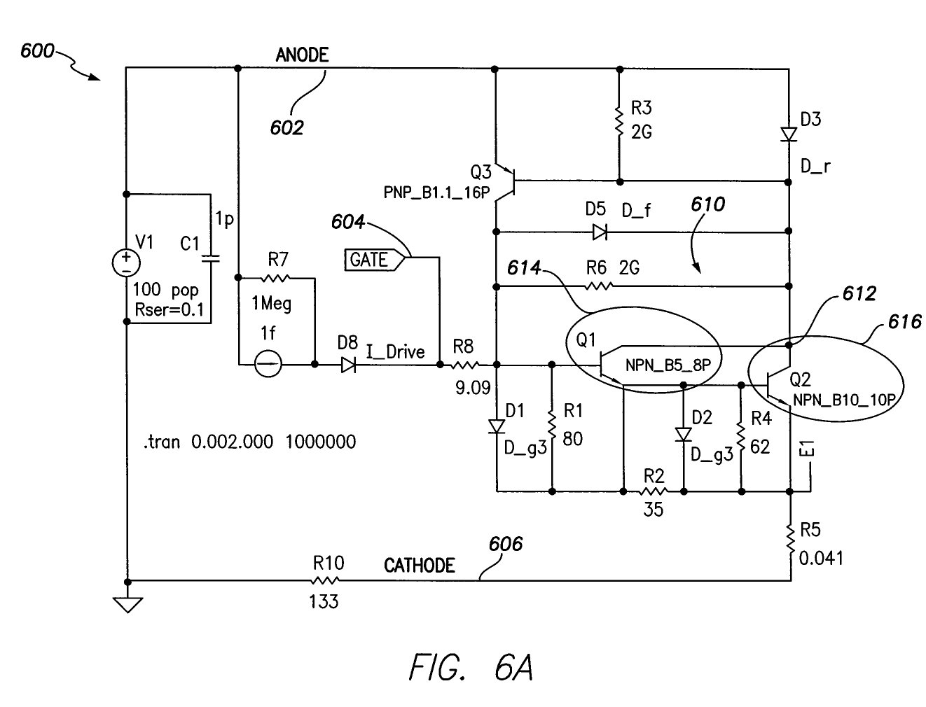

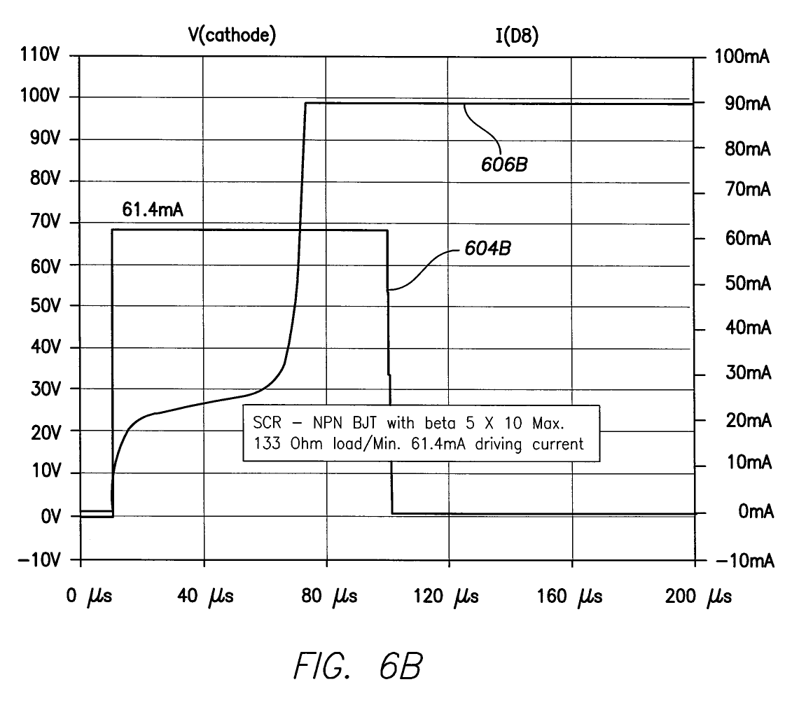

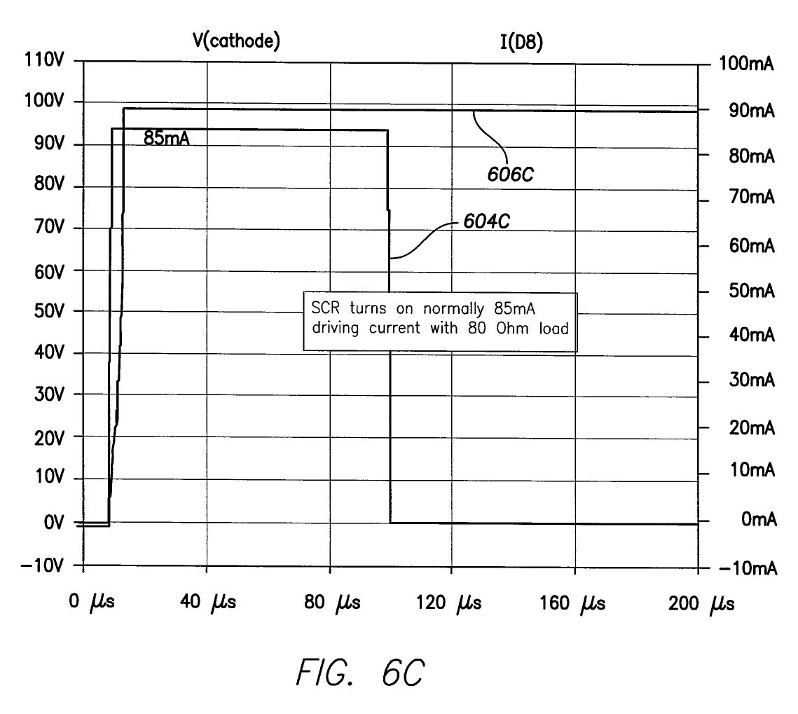

FIG. 6A illustrates a schematic design of an SCR 600 formed in accordance with an embodiment. The SCR 600 includes an anode 602, a gate node 604 and a cathode 606. A transistor Q3 is located between the anode 602 and gate node 604, while resistors R1 and R2 are located between the gate node 604 and the cathode 606. A Darlington transistor pair 610 is positioned between a common collector node 612 and the cathode 606. The DTP 610 includes first and second stages 614 and 616 that are joined at the common collector node 612.

The transistor Q3 represents a PNP type transistor that has a beta of 1.1 and a junction capacitance under zero biasing of 16 PicoFarads. The first and second stages 614 and 616 include transistors Q1 and Q2, respectively. The transistor Q1 in the front end or first stage 614 represents an NPN type transistor having a beta value of 5.0. The transistor Q1 has a junction capacitance under zero biasing of 8 PicoFarads. The transistor Q2 in the output or second stage 616 represents an NPN type transistor having a beta value of 10 and a junction capacitance under zero biasing of 10 PicoFarads. The approximate Miller capacitance of the DTP 610 is 8×[5×10]=400P when the junction capacitance of the transistor Q2 is not counted.

FIG. 6B illustrates a simulation of the output of the SCR 600 where the horizontal axis plots time in microseconds, the left vertical axis plots voltage in Volts and the right vertical axis plots current in milliamps. A supply voltage of 100V was supplied to the anode 602. The current square wave 604B represents the triggering signal supplied to the gate anode 604 of the SCR 600. The signal 606B represents the output voltage delivered to the load denoted as resistor R10 in FIG. 6A. The output (shocking) signal 606B moves from a low level state to a high level and reaches a steady state, within less than 80 usec after the leading, rising edge of the trigger signal 604B. As shown by the signal 606B, when connected to a high impedance load (e.g., 133 Ohms) at resistor R10, a triggering signal with a current level of 61.4 mA was sufficient to cause the SCR 600 to operate in a designed (normal) output drive capability.

FIG. 6C illustrates another simulation result of the output of the SCR 600 where the horizontal axis plots time in microseconds, the left vertical axis plots voltage in Volts and the right vertical axis plots current in milliamps. A square wave 604C with amplitude of 85 mA was delivered as the triggering signal to the gate anode 604 of the SCR 600. The output (shocking) signal 606C switched from the low level to the high level steady state within less than 20 usec. following the leading rising edge of the trigger signal 604C. The output signal 606C was delivered to a medium impedance load (e.g., 80 Ohms).

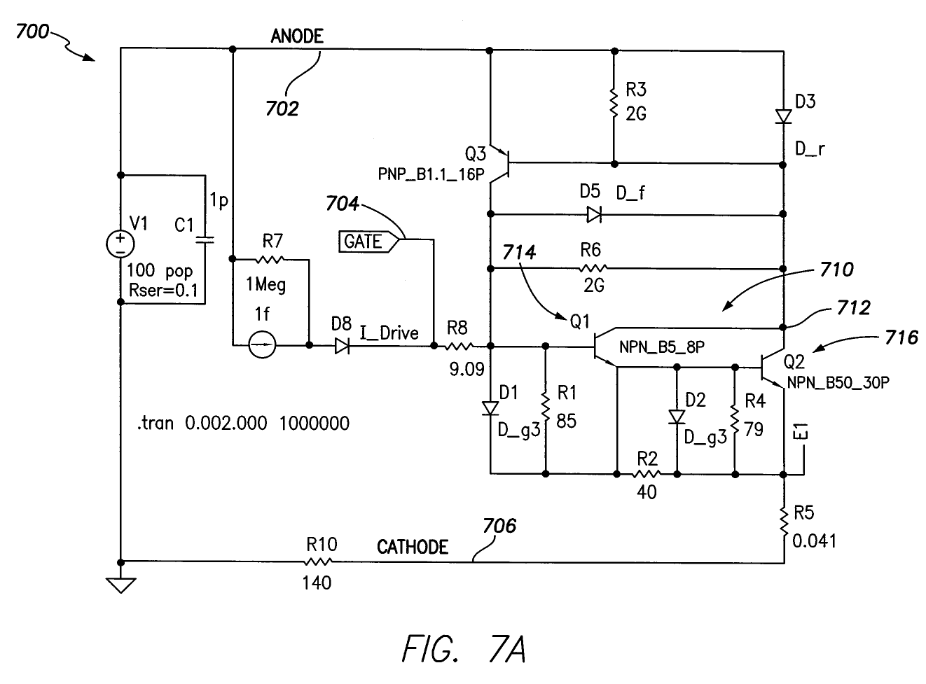

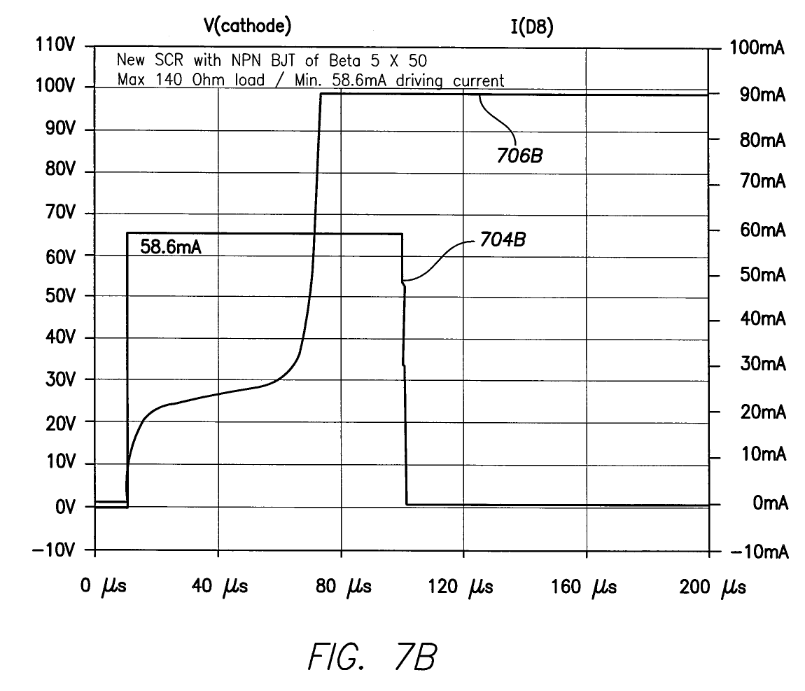

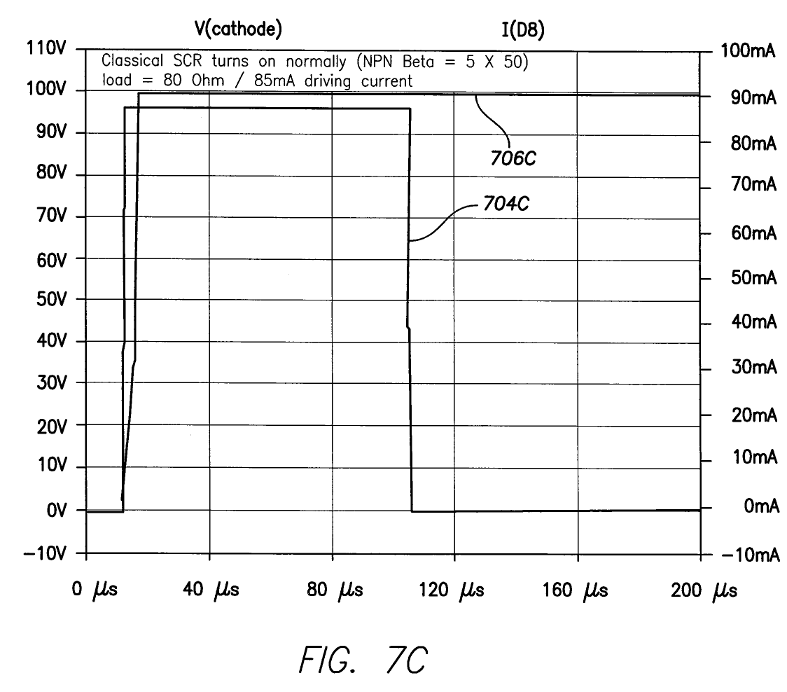

FIG. 7A illustrates a schematic design of an SCR 700 formed in accordance with an embodiment. The SCR 700 includes an anode 702, a gate node 704 and a cathode 706. A transistor Q3 is located between the anode 702 and gate node 704, while resistors R1 and R2 are located between the gate node 704 and the cathode 706. A Darlington transistor pair 710 is positioned between a common collector node 712 and the cathode 706. The DTP 710 includes first and second stages 714 and 716 that are joined at the common collector node 712.

The transistor Q3 represents a PNP type transistor that has a beta of 1.1 and a junction capacitance under zero biasing of 16 PicoFarads. The first and second stages 714 and 716 include transistors Q1 and Q2, respectively. The transistor Q1 in the front end or first stage 714 represents an NPN type transistor having a beta value of 5.0 and a junction capacitance under zero biasing of 8 PicoFarads. The transistor Q2 in the output or second stage 716 represents an NPN type transistor having a beta value of 50 and a junction capacitance under zero biasing of 30 Picofarads. The approximate Miller capacitance of the DTP 710 is 8×[5×50]=2000P when the junction capacitance of the transistor Q2 is not counted.

FIG. 7B illustrates a simulation result of the output of the SCR 700 where the horizontal axis plots time in microseconds, the left vertical axis plots voltage in Volts and the right vertical axis plots current in milliamps. A supply voltage of 100V was supplied to the anode 702. A load of 140 Ohms is attached to the output node. The square wave 704B with an amplitude of 58.6 mA represents the triggering signal supplied to the gate anode 704 of the SCR 700. The signal 706B represents the output voltage delivered to the load denoted as resistor R10. The output (shocking) signal 706B moves from a low level state to a high level and reaches a steady state within less than 70 usec after the leading, rising edge of the trigger signal 704B. As shown by the signal 706B, when connected to a high impedance load (e.g., 140 Ohms), a triggering signal with a current level of 58.6 mA was sufficient to cause the SCR 700 to operate in a designed (normal) output drive capability.

FIG. 7C illustrates another simulation of the output of the SCR 700 where the horizontal axis plots time in microseconds, the left vertical axis plots voltage in Volts and the right vertical axis plots current in milliamps. A square wave 704C with amplitude of 85 mA was delivered as the triggering signal to the gate anode 704 of the SCR 700. The output (shocking) signal 706C switched from the low level to the high level steady state within less than 20 usec. following the leading rising edge of the trigger signal 704C. The output signal 706C was delivered to a medium impedance load (e.g., 80 Ohms).

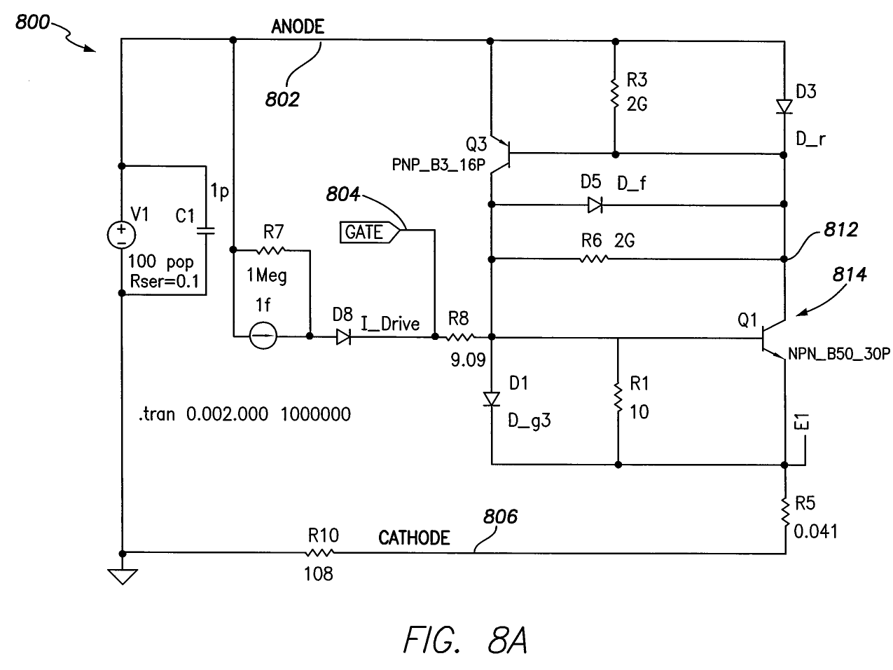

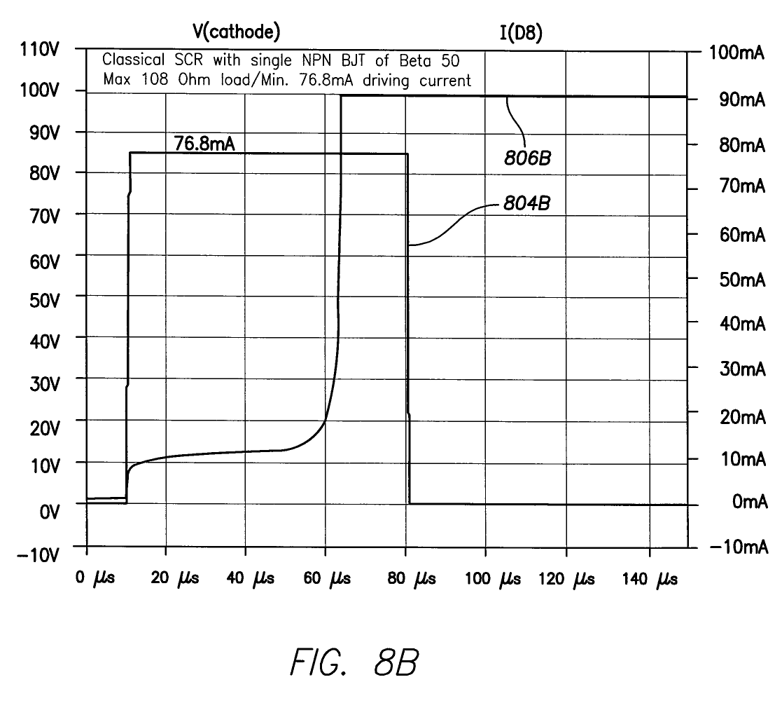

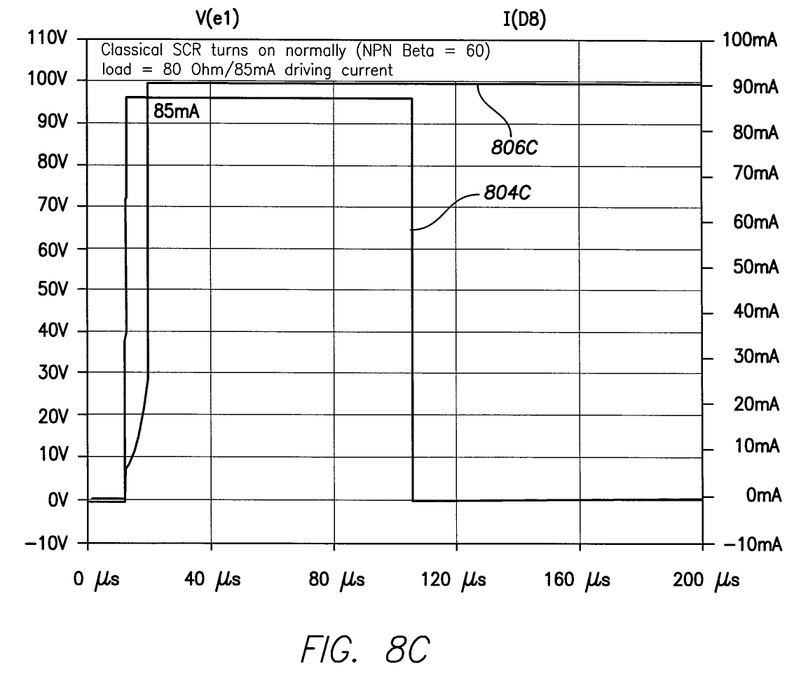

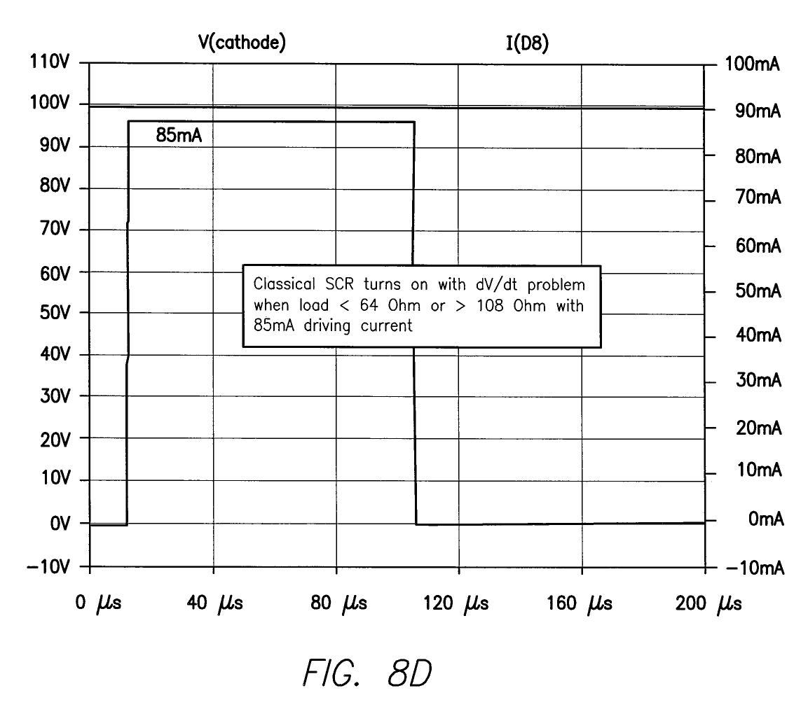

FIG. 8A illustrates a schematic design of a classical SCR 800 formed in accordance with a conventional design. The SCR 800 includes an anode 802, a gate node 804 and a cathode 806. A transistor Q3 is located between the anode 802 and gate node 804, while resistor R1 is the gate shunt resistor. A single transistor Q1 (also denoted as 814) is positioned between a collector node 812 and the cathode 806.

In the example of FIG. 8A, the transistor Q3 represents a PNP type transistor that has a beta of 3.0 and a junction capacitance under zero biasing of 16 PicoFarads. The single SCR transistor Q1 represents an NPN type transistor having a beta value of 50.0. The SCR transistor Q1 has a junction capacitance under zero biasing of 30 PicoFarads. The approximate miller capacitance is about 30×50=1500P. It should be noted, that if the beta of the PNP transistor Q3, in the conventional configuration of FIG. 8A, is set to the same beta value as the new SCR topology such as in FIG. 6A (beta=1.1), performance of the conventional configuration is downgraded. One purpose of utilizing a low beta for the PNP transistor Q3 in the new SCR topology is to pair (or balance) the lower NPN transistors Q1 and Q2 in the first and second stages (e.g. 614 and 616, or 714 and 716).

FIG. 8B illustrates a simulation of the output of the classic SCR 800, where in order to fire normally with a maximum load R10 at 108 Ohm, a minimum triggering current of at least 76.8 mA is needed. In FIG. 8B, the horizontal axis plots time in microseconds, the left vertical axis plots voltage in Volts and the right vertical axis plots current in milliamps. A supply voltage of 100V was supplied to the anode 802. The current square wave 804B represents the triggering signal supplied to the gate anode 804 of the SCR 800. The signal 806B represents the output voltage delivered to the load denoted as resistor R10. The output (shocking) signal 806B moves from a low level state to a high level and reaches a steady state within less than 60 usec after the leading, rising edge of the trigger signal 804B. As shown by the signal 806B, when connected to an impedance load of 108 Ohms, a triggering signal with a current level of 76.8 mA was needed to cause the SCR 800 to operate in a designed (normal) output drive manner.

From the above discussion and attached Figures, a general comparison can be made between the classical SCR 800 versus the new SCR 600 of FIG. 6A. The new SCR 600 sets the first stage Darlington Q1 to have a Beta=5, and the total Darlington Beta to equal 50 which is same as in the classical SCR 800 single stage Q1 (Beta=50). However, the new SCR 600 has a Miller capacitance of 400p which is significantly smaller than in the classical SCR 800 which has a Miller capacitance of 1500p. The simulation results show the following:

1) New SCR 600 can reduce about the triggering current by 20% less than the triggering current in the Classical SCR 800 (61.4 mA V.S 76.8 mA) under their maximum loads.

2) Both with minimum triggering current, the new SCR 600 can drive up to a 133 Ohm maximum load which is about 23% higher than the maximum load of the classic SCR 800 (133 Ohm v.s. 108 Ohm).

The simulation comparisons show that even though the classic SCR 800 has 3.75 times higher Miller capacitance than the new SCR 600 (1500p vs. 400p), the dV/dt problem of the classical SCR 800 is still worse than that of the new SCR 600 when it exceed its maximum loading, and especially when the load exceeds 108 Ohm in the SCR 800 (see FIG. 8D). This is because the SCR 600 has a lower beta and lower sensitivity in first stage Q1, but the total beta of the Darlington pair is the same as the single stage Q1 in the classic SCR 800. This shows that the new topology can split the tradeoffs into two stages which a single stage NPN transistor can not achieve, and improve both the triggering current and maximum load performance.

From the above discussion and attached Figures, a general comparison can be made between the classical SCR 800 versus the new SCR 700 of FIG. 7A. The new SCR 700 keeps the first Darlington stage (Q1) Beta=5 as the SCR 600 did, but increases the 2nd stage (Q2) beta to 50. This renders the total Beta of the Darlington pair to be 250 and the Miller capacitance to be 8×[5×50]=2000P. In this comparison, the new SCR 700 has both a larger Beta and a larger Miller capacitance than the classical SCR 800. The simulation results show the following:

1) New SCR 700 further reduces the triggering current about 23.7% below the triggering current of the Classical SCR 800 under their maximum load (58.6 mA v.s. 76.8 mA).

2) Both with minimum triggering current, the new SCR 700 can drive up to a 140 Ohm maximum load which is about 30% higher than the maximum load of Classic SCR 800 (140 Ohm v.s. 108 Ohm).

The simulation comparisons show that the new SCR 700 not only splits the tradeoffs in two stages (which a single stage NPN transistor can not achieve), but also aggressively increases the total Beta of the Darlington pair and Miller capacitance to further improve both the triggering current and maximum load performance. The large Miller capacitance will also help to improve the external noise immunity from the gate which in turn helps to reduce the dV/dt and dl/dt problem.

Also, the SCR 700 keeps the first stage Beta (=5) unchanged as in SCR 600, but increased the total Beta and Miller capacitance in the Darlington pair (Beta 250 v.s. 50 and Miller capacitance 2000p v.s. 400p). As a result, SCR 700 further reduces the triggering current by about 3.7% (58.6 mA v.s. 61.4 mA) and increases the maximum load by about 7% (140 Ohm v.s. 133 Ohm) based on classical SCR 800 simulation result.

FIG. 8C illustrates a simulation result of the output of the classic SCR 800 when the load at R10 is 80 Ohms and the drive triggering current is 85 mA. A square wave 804C with amplitude of 85 mA was delivered as the triggering signal to the gate anode 804 of the SCR 800. The output (shocking) signal 806C switched from the low level to the high level steady state in over 20 usec. following the leading rising edge of the trigger signal 804C.

From the firing curves in FIGS. 8B and 8C, it can be seen that the firing speed of the classic SCR 800 is slower than those of the new SCR 600, 700.

Next the discussion turns to FIG. 8D, which illustrates a simulation result of the output of the classic SCR 800 when the load at R10 is less than 64 Ohm or greater than 108 Ohm with enough driving current is applied (e.g. 85 mA). As illustrated in FIG. 8D, the SCR 800 was spuriously (prematurely) turned ON due to the dV/dt problem. More specifically, the SCR 800 was spuriously fired prior to, or without, a trigger event from the gate because the rate of rise of the voltage between the anode to cathode was too large.

The new SCR 500, 600, 700 does not experience spurious or premature firing when the load is less than 64 Ohms or greater than 108 Ohms. Instead, the new SCR 500, 600 and 700 are configured to operate with a desired (normal) output drive capability over a broader range of loads. For example, the new SCR 600 may operate with a normal output drive capability (e.g., no dV/dt problem) when the load is equal to or between 24 Ohms and 133 Ohm. As a further example, the new SCR 700 may operate with a normal output drive capability (e.g., no dV/dt problem) when the load is equal to or between 23 Ohms and 140 Ohm.

The results in FIG. 8D show that even though the classic SCR 800 has 3.75 times higher miller capacitance than the new SCR500, 600 or 700 topology (1500p vs. 400p), the classic SCR 800 experiences a worse dV/dt problem than the new SCR 500, 600, 700 topology. The classic SCR 800 experienced the dV/dt problem over a wider range of load impedances, namely below 64 Ohm or above 108 Ohm. This is because the new SCR 500, 600, 700 topology has a lower beta and lower sensitivity in the transistor Q1, but the total beta of the Darlington (DTP 610, 710) is the same as the total beta in the classic SCR 800. In certain embodiments, the DTP may include two stages (each including a NPN transistor) which affords the opportunity to split the operational characteristic tradeoffs between the two stages. As one example, the DTP with two NPN transistors gives a SCR designer more room to achieve a predetermined (e.g., optimized) level for sensitivity, gain, and driving capability. For example, the designer can use a small power, low beta BJT in the first stage (also referred to as the front end stage) and a large power, higher beta BJT in the second stage (also referred to as the output stage) to reduce triggering current and increase the output driving capability, which will also reduce the holding current.

In certain embodiments, the DTP may be configured to be used with a ultra low power CMOS IC based driver. The CMOS IC driver will directly drive a large powered SCR application, such as the high voltage bridge in an IMD. In certain embodiments, the DTP will simplify design, increase reliability, save circuit space and greatly reduce cost. In certain embodiments, the DTP 510 affords high impedance driving capability and a high reliability design that is well fit for critical circuit applications, such as output H-bridge stage in an IMD.

Embodiments described herein operate well under high impedance load, while greatly reducing the potential for dl/dt and dV/dt problems without sacrificing sensitivity or large beta values of the internal BJT transistor. Embodiments described afford new SCR topologies that have lower drive and holding currents. Darlington based transistor configurations, that have lower bandwidth, exhibit intrinsic immunity to external gate triggering noise, and thus a low valued gate shunting resistor is no longer required to absorb the gate noise.

Embodiments described herein split an SCR's single NPN transistor into two Darlington based transistors, thereby affording an SCR designer more room to optimize the SCR's natural tradeoffs between dl/dt, dV/dt, high impedance driving capability, triggering current and holding current.

Embodiments described herein afford SCR topologies that are a best fit for ultra low power applications, such as ultra low power CMOS IC direct driven H-bridge circuits in IMDs, as well as other applications in that utilize high voltage outputs and low power designs. Embodiments described herein introduce new SCR topologies that reduce the internal speed or bandwidth of the BJT.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the subject matter disclosed herein without departing from its scope. While the dimensions, types of materials and coatings described herein are intended to define the parameters of the subject matter disclosed herein, they are by no means limiting and are exemplary embodiments. Many other embodiments will be apparent to those of skill in the art upon reviewing the above description. The scope of the subject matter disclosed herein should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means—plus-function format and are not intended to be interpreted based on 35 U.S.C. §112, sixth paragraph, unless and until such claim limitations expressly use the phrase “means for” followed by a statement of function void of further structure.

1. A high voltage switching and control circuit for an implantable medical device (IMD), comprising:
a high voltage positive (HVP) node configured to receive a positive high voltage signal from a high energy storage source;
a high voltage negative (HVN) node configured to receive a negative high voltage signal from a high energy storage source;
first and second output terminals configured to be connected to electrodes for delivering high voltage energy; and
first and second Silicon Controlled Rectifier (SCR) switches connected to the HVP node, the first and second SCR switches connected to the first and second output terminals respectively, wherein the first and second SCR switches each include a Darlington transistor pair having a first transistor stage joined to a second stage transistor at a common collector node.

2. The circuit of claim 1, wherein the first and second stages of the Darlington transistor pair are joined such that an emitter of the first stage is connected to a base of the second stage.

3. The circuit of claim 1, wherein the first and second stages of the Darlington transistor pair are joined such that emitters of the first and second stages are joined to first and second output nodes that have a shunt resistor provided therebetween.

4. The circuit of claim 1, wherein the first and second stages have operational parameters set such that a predetermined triggering current will turn ON and hold ON the corresponding SCR switch.

5. The circuit of claim 1, wherein the first and second stages have operational parameters set such that the corresponding SCR switch exhibits predetermined dV/dt and dl/dt characteristics.

6. The circuit of claim 1, wherein the first and second stages have first and second beta values, respectively, that are set to limit a rate of rise of an anode to gate voltage across the Darlington transistor pair in a predetermined manner to thereby prevent false triggering of the corresponding SCR switch when connected to a predetermined load and supplied with a predetermined triggering signal.

7. The circuit of claim 1, wherein the first and second stages are configured to exhibit corresponding beta and power operational parameters, the beta and power operational parameters of the first stage being lower than the beta and power operational parameters of the second stage to reduce a sensitivity at the gate node of the first stage and to reduce a drive current delivered to the gate node of the first stage.

8. The circuit of claim 1, wherein the first and second stages are configured to exhibit corresponding betas and power, the beta and power of the second stage being higher than the beta and power of the first stage to increase an output drive capability of the SCR switch.

9. The circuit of claim 1, wherein the second output terminal represents a SVC terminal configured to be connected to a Superior Vena Cava (SVC) electrode.

10. (canceled)

11. A method for operating a high voltage switching and control circuit in an implantable medical device (IMD), the method comprising:
configuring a high voltage positive (HVP) node to receive a positive high voltage signal from a high energy storage source;
configuring a high voltage negative (HVN) node to receive a negative high voltage signal from a high energy storage source;
configuring first and second output terminals to be connected to electrodes for delivering high voltage energy;
connecting first and second Silicon Controlled Rectifier (SCR) switches to the HVP node, the first and second SCR switches connected to the first and second output terminals respectively, wherein the first and second SCR switches each include a Darlington transistor pair having a first transistor stage joined to a second stage transistor at a shared collector node.

12. The method of claim 11, wherein the first and second stages of the Darlington transistor pair are joined such that an emitter of the first stage is connected to a base of the second stage.

13. The method of claim 11, wherein the first and second stages of the Darlington transistor pair are joined such that emitters of the first and second stages are joined to first and second output nodes that have a shunt resistor provided therebetween.

14. The method of claim 11, further comprising setting operational parameters of the first and second stages such that a predetermined triggering current will turn ON and hold ON the corresponding SCR switch.

15. The method of claim 11, further comprising setting operational parameters of the first and second stages such that the corresponding SCR switch exhibits predetermined dV/dt and dl/dt characteristics.

16. The method of claim 11, further comprising setting first and second beta values for the first and second stages, respectively, to limit a rate of rise of an anode to gate voltage across the Darlington transistor pair in a predetermined manner to prevent false triggering of the corresponding SCR switch when connected to a predetermined load and supplied with a predetermined triggering signal.

17. The method of claim 11, further comprising configuring the first and second stages to exhibit corresponding beta and power operational parameters, the beta and power operational parameters of the first stage being lower than the beta and power operational parameters of the second stage to reduce a sensitivity at the gate node of the first stage and to reduce a drive current delivered to the gate node of the first stage.

18. The method of claim 11, further comprising configuring the first and second stages to exhibit corresponding betas and power, the beta and power of the second stage being higher than the beta and power of the first stage to increase an output drive capability of the SCR switch.

19. The method of claim 11, wherein the second output terminal represents a SVC terminal configured to be connected to a Superior Vena Cava (SVC) electrode.

20. (canceled)
